(19) United States
(12) Patent Application Publication
(10) Pub. No.: US 2007/0200233 A1
(43) Pub. Date: Aug. 30, 2007

(54) Bond pad structures with reduced coupling noise

(75) Inventor: Hsien-Wei Chen, Sinying City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/302,698

(22) Filed: Dec. 14, 2005

(51) Int. Cl. H01L 23/48; H01L 23/52; H01L 29/40

(52) U.S. Cl. 257/734

(57) ABSTRACT

A bond pad structure with reduced coupling noise is provided. An exemplary embodiment of the bond pad structure comprises a first dielectric layer with a first conductive layer therein, wherein the first conductive layer is grounded. A second dielectric layer with a second conductive layer, a plurality of conductive contacts and a conductive line therein is formed to overly the first dielectric layer. A bond pad layer is formed over the second conductive layer, wherein the second conductive layer and the first conductive layer are superimposed, the bond pad layer and the second conductive layer have a surface area less than that of the first conductive layer, and the conductive contacts electrically connect the first conductive layer to form a noise shield from the sides and bottom of the bond pad layer.

### BACKGROUND OF THE INVENTION

1. Field of the Invention

The present invention relates to semiconductor fabrication, and in particular to a bond pad structure for a semiconductor device.

2. Description of the Related Art

Conventional semiconductor devices typically comprise a semiconductor substrate and a plurality of sequentially formed inter-layer dielectrics and interconnected metallization layers defining conductive patterns. An integrated circuit is formed comprising a plurality of conductive patterns including conductive lines separated by interwiring spacings, and a plurality of interconnect lines, such as bus lines, bit lines, word lines and logic interconnect lines. Typically, the conductive patterns on different metallization layers are electrically connected by a conductive plug filling a via opening, while a conductive plug filling a contact opening establishes electrical contact with an active region on a semiconductor substrate, such as a source/drain region. Conductive lines are formed in trenches, which typically extend substantially horizontally with respect to the semiconductor substrate. Semiconductor chips comprising five or more levels of metallization are becoming more prevalent as device geometries are reduced to submicron levels.

In general, the entire surface of a semiconductor device is covered with a final passivation film such as a plasma SiN film after a metal wiring layer electrode layer is formed. A hole is formed in the final passivation layer to partly expose the electrode layer so that the exposed portion thereof can be used as a bonding pad section. An external package pin is connected to the bonding pad section by a bonding technique such as wire bonding, thereby forming a bonding structure.

Normally, the bonding structure is formed with a feature size much larger than that of the conductive lines or devices in the semiconductor device, functioning as a power input/output (I/O), which may work under a high clock frequency of about 1 GHz or above. Thus, the bonding structure becomes a noise source and inevitably causes inductance effects and affects performance of adjacent conductive lines or devices formed in close proximity thereto. Coupling noise therefore occurs, affecting the conductive lines or devices formed in proximity to the bonding structure.

### BRIEF SUMMARY OF INVENTION

To reduce and prevent bonding structure induced coupling noise, bond pad structures with reduced coupling noise are provided. An exemplary embodiment of a bond pad structure comprises a first dielectric layer with a first conductive layer therein, wherein the first conductive layer is grounded. A second dielectric layer with a second conductive layer, a plurality of conductive contacts and a conductive line therein is formed to overly the first dielectric layer. A bond pad layer is formed over the second conductive layer, wherein the second conductive layer and the first conductive layer are superimposed, the bond pad layer and the second conductive layer have a surface are less than that of the first conductive layer, and the conductive contacts electrically connect the first conductive layer to form a noise shield from the sides and bottom of the bond pad layer.

An exemplary embodiment of a semiconductor device comprises a first dielectric layer with a first conductive layer and a signal line therein, wherein the first conductive layer is grounded. A second dielectric layer with a second conductive layer, a plurality of conductive contacts and a conductive line therein, overlying the first dielectric layer. A bond pad layer overlying the second conductive layer and a conductive bond over the bond pad, wherein the second conductive layer and the first conductive layer are superimposed, the bond pad layer and the second conductive layer have a surface less than that of the first conductive layer, and the conductive contacts electrically connect the first conductive layer to form a noise shield from the sides and bottom of the bond pad layer such coupling noises induced by operations of the conductive bond is reduced.

An exemplary embodiment of a method of reducing coupling noise comprises providing a dielectric layer with a signal line therein and a bonding structure thereon, wherein the bonding structure comprises a bond pad layer formed on the dielectric layer and a conductive bond over the bond pad layer. A shielding structure is formed in embedded in the dielectric layer at a place under the bond pad layer, wherein the shielding structure comprises a grounded conductive layer and a plurality of contacts formed over the grounded conductive layer, extending along opposing edges of the bond pad layer.

A detailed description is given in the following embodiments with reference to the accompanying drawings.

### BRIEF DESCRIPTION OF DRAWINGS

The present invention can be more fully understood by reading the subsequent detailed description and examples with references made to the accompanying drawings, wherein:

FIG. 1 is a schematic top view showing a semiconductor device having a bond pad structure with reduced coupling noise according to an embodiment of the invention;

FIG. 2 shows a cross section taken along line 2-2 of FIG. 1;

FIG. 3 is a schematic top view showing a semiconductor device having a bond pad structure with reduced coupling noise according to another embodiment of the invention, having an conductive line passing under the bond pad structure;

FIG. 4 shows a cross section taken along line 4-4 of FIG. 3;

FIG. 5 is a schematic top view showing a semiconductor device having bond pad structure with reduced coupling noise according to yet another embodiment of the invention; and

FIG. 6 is a schematic top view showing a semiconductor device having a bond pad structure with reduced coupling noise according to yet another embodiment of the invention, having an conductive line passing under the bond pad structure.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

Bond pad structures with reduced coupling noise are now described here in greater detail. Some embodiments of the invention, such as the exemplary embodiments describe, can potentially provide a shielding structure embedded in a dielectric layer under the bond pad layer for forming a conductive bond thereon, wherein the shielding structure comprises a conductive layer having a surface area substantially larger than that of the bond pad layer and a plurality of contacts on the conductive layer formed on at least two opposing sides of the bond pad layer.

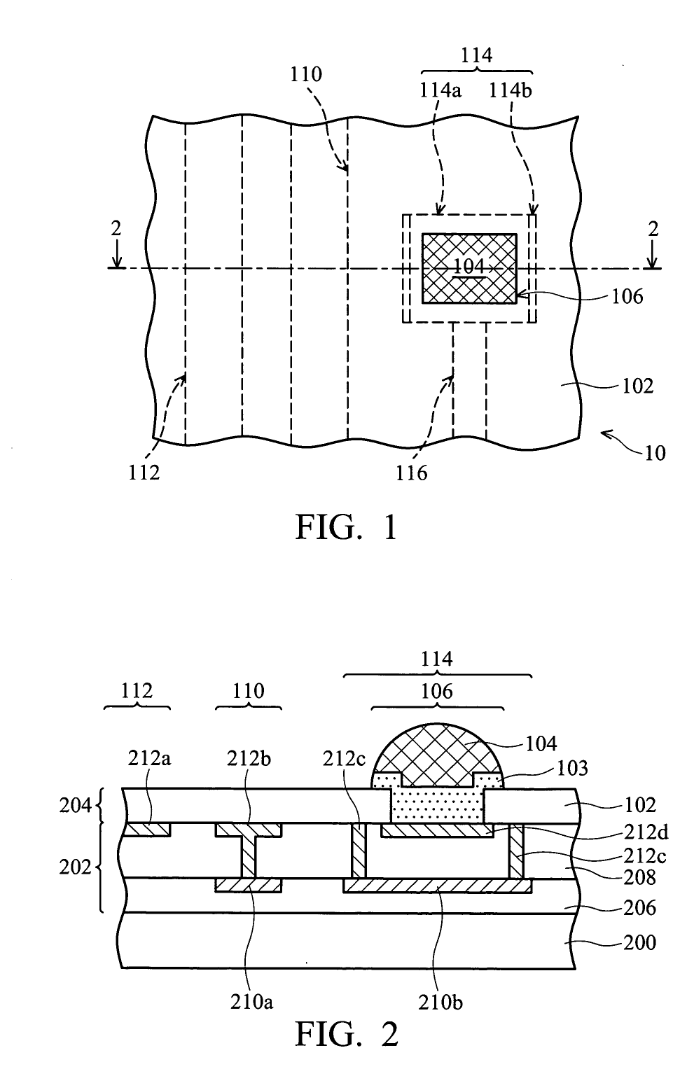

FIG. 1 shows a top view of a part of an exemplary semiconductor device 10 having a bond pad structure with reduced coupling noise. As shown in FIG. 1, the semiconductor device 10 is provided with a topmost passivation layer 102, exposing a conductive bond 104 for input/output (I/O) connection therein. The conductive bond 104 is formed over a bonding pad region 106 in the passivation layer 102. Conductive lines 110 and 112, shown by dotted lines, are provided underlying the passivation layer 102 and both extend along a side of the bonding pad region 106. One or more of the conductive lines 110 and 112 may function as a signal line. Normally, the semiconductor device 10 may be an RF device and the conductive bond 104 may work under a high clock frequency of about 1 GHz or above during operation of the semiconductor device 10, thus, coupling noise is induced to the adjacent conductive lines thereto.

Still referring to FIG. 1, the conductive lines 110 and 112 are illustrated as conductive lines disposed in parallel, but the arrangement is not limited thereto. A noise shielding structure 114 is provided to overlap the bonding pad region 106 from the bottom and opposite sides thereof, including a planar portion 114a and a pair of sidewall portions 114b overlying the planar portion 114a which are both shown by dotted lines here, thus coupling noise induced by the conductive bond 104 is reduced or prevented from affecting the adjacent conductive lines 110 and 112 during operation of the conductive bond 104. Normally, the bonding pad region 106 has a surface of about 3000˜6000 μm², for example, and the planar portion 114a of the noise shielding structure 114 has a surface of about 3000˜7000 μm², for example. Therefore, the planar portion 114a of the noise shielding structure 114 and conductive bond 104 are superimposed and have a surface ratio of about 1:1˜1:1.5 therebetween. Herein, a conductive line 116, shown by dotted line, is provided under the passivation layer 102 and is located at an area adjacent to the noise shielding structure 114. Since the coupling noise protection is provided by the noise shielding structure 114, the conductive lines 110 and 112 can thus be formed at a distance closer to the bonding pad region 106, substantially about 0.1˜5 μm and preferably about 0.1˜1 μm from the bonding pad region 106, thus increasing circuitry integration near the bond pad region. Moreover, the conductive line 116 electrically connects the planar portion 114a of the noise shielding structure 114 and is connected to a bias such as a ground bias to thereby provide the noise shielding structure 114 with such noise shielding effects. It is noted that the conductive line 116 functioning as the ground line here can connect the noise shielding structure 114 not only from the planar portion 114a thereof, but also from the sidewall portions 114b thereof which is not shown here for simplicity. Moreover, the noise shielding structure 114 can further connect one or more ground lines to provide better ground performance and is not limited by the connection illustrated in FIG. 1.

FIG. 2 shows a cross section taken along the line 2-2 of FIG. 1, illustrating a part of the semiconductor device 10. In FIG. 2, an essentially finished substrate 200 is provided, having an interconnecting level 202 and a bond pad level 204 sequentially stacked thereon. It is understood that the substrate 200 includes the necessary constituent substrate layer and its associated metal and insulating layers to fully define the circuitry for intended functionality. Herein, the interconnecting level 202 formed over the substrate 200 includes dielectric layers 206 and 208 having a plurality of conductive segments therein, respectively. As shown in FIG. 2, the dielectric layer 206 is formed with isolated conductive segments 210a and 210b therein and the dielectric layer 208 is formed with isolated conductive segments 212a, 212b, 212c and 212d therein, wherein the conductive segments 212b electrically connect the underlying conductive segment 210a, functioning as an inter-level wiring, and the conductive segments 212c electrically connects the underlying conductive segment 210b, functioning as a noise shield for the overlying conductive bond pad. Conductive segments 210a, 210b, 212a-d may be formed by, for example, conventional line fabrications or damascene processes and comprise conductive metal such as copper, aluminum, or alloys thereof.

Still referring to FIG. 2, the bond pad level 204 is formed over the interconnecting level 202 and includes a passivation layer 102 with a bond pad layer 103 formed therein. The bond pad layer 103 is formed through the passivation layer 102 over a portion of the passivation layer 103, electrically connecting the underlying conductive segment 212d. Conductive bonding such as the conductive bump 104 is formed on the bond pad layer 103, functioning as an I/O window. The bond pad layer 103 may be, for example, a AlCu pad formed by sequential deposition and patterning defining processes and the conductive bump may be, for example, a solder bump.

As shown in FIG. 2, the conductive segment 210b, functioning as the planar portion 114a of the noise shielding structure 114, normally has a width greater than that of a bond pad layer 103 formed in the bonding pad region 106, and the conductive segments 212c formed on the conductive segment 210b, functioning as the sidewall portions 114b of the noise shielding structure 114, extends on opposite sides of the bond pad layer 103 and along the adjacent conductive segments 212a and 212b. Therefore, coupling noise induced by the conductive bump 104, and transmitted to the adjacent conductive segments 212a and 212b can be reduced or prevented by the noise shielding structure 114 and undesirable effects on functional performance is thus prevented.

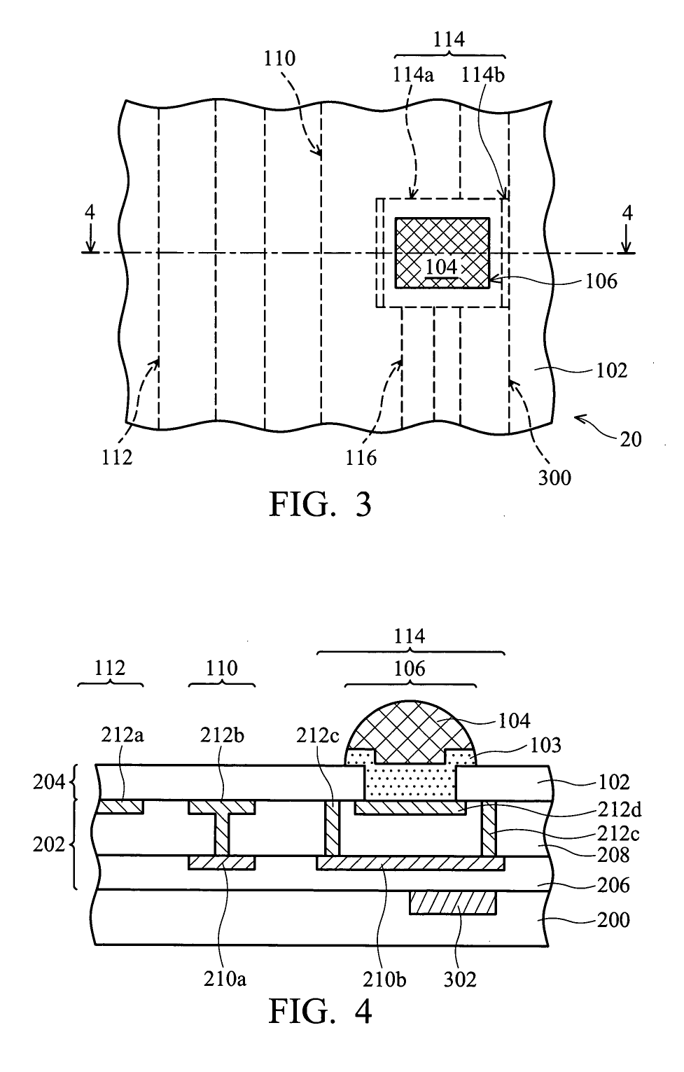

FIGS. 3 and 4 show another exemplary embodiment of the semiconductor device 20 similar to the semiconductor device 10 illustrated in FIGS. 1 and 2, wherein similar labels represent the same elements and only differences between the semiconductor device 20 and the semiconductor device 10 are described in greater detail.

As shown in FIG. 3, a top view of a part of the semiconductor device 20 having a bond pad structure with reduced coupling noise is illustrated. The semiconductor device 20 is provided with a conductive line 300 formed therein, substantially passing through the bonding pad region 106 from thereunder.

In FIG. 4, a cross section taken along the line 4-4 of FIG. 3 is illustrated. The substrate 200 is now provided with a conductive segment 302 thereon and is located substantially under the bonding pad region 106, functioning as the conductive line 300 illustrated in FIG. 3. Since the noise shielding structure 114 including the conductive segments 212c and 210b is provided between the conductive segment 302 and the conductive bond 104, coupling noise induced by the conductive bump 104 to the conductive segments 302 during its operation can therefore be reduced or prevented by the noise shielding structure 114 and undesirable effects on functional performance is thus prevented.

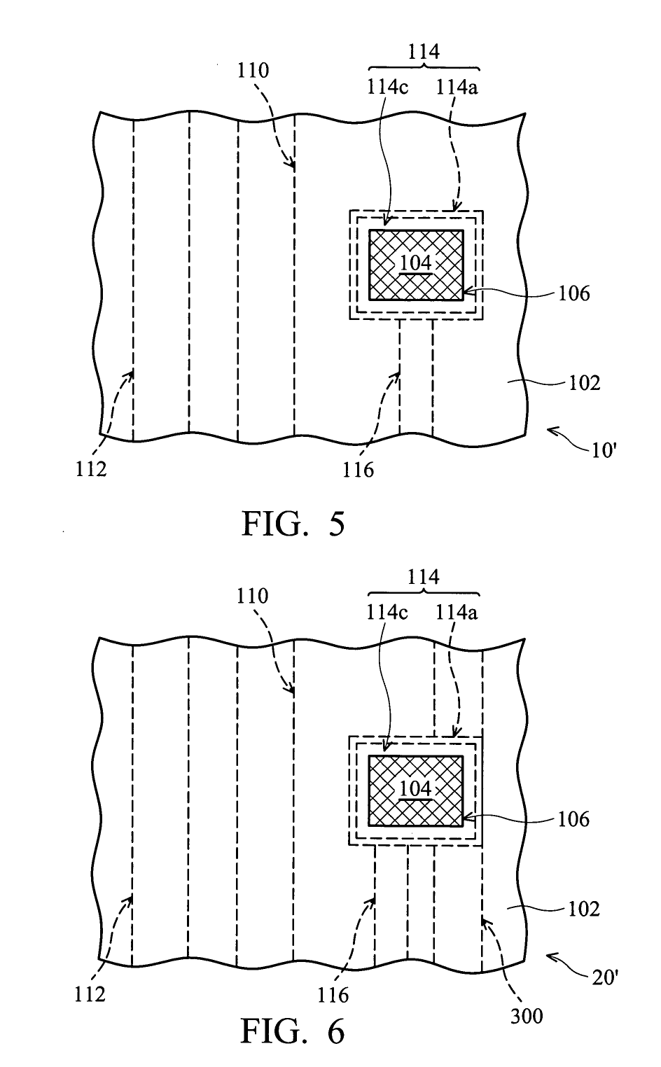

FIGS. 5 and 6 are schematic top views respectively showing a semiconductor device 10′ and 20′ having a bond pad structure with reduced coupling noise similar to that illustrated in FIGS. 1 and 3, respectively. Compared to the semiconductor devices 10 and 20 shown in FIGS. 1 and 3, the noise shielding structure 114, respectively shown in FIGS. 5 and 6, includes a planar portion 114a and a sidewall portion 114c overlying the planar portion 114a, both shown by dotted lines, to thereby reduce coupling noises induced by the conductive bond 104 and prevent coupling noise from affecting the adjacent conductive lines 110 and 112 during operation of conductive bond 104. The sidewall portion 114c shown in FIGS. 5 and 6 now surrounds the conductive bump 104 from all sides thereof to provide better protection against the effects of coupling noise. The planar portion 114a and the sidewall portion 114c of the noise shielding structure 114 can be composed of the conductive segments 210b and 212c illustrated in FIGS. 2 and 4 and is not described in detail, for simplicity.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A bond pad structure with reduced coupling noise, comprising:
a first dielectric layer with a first conductive layer therein, wherein the first conductive layer is grounded;
a second dielectric layer with a second conductive layer, a plurality of conductive contacts and a conductive line therein, overlying the first dielectric layer; and
a bond pad layer overlying the second conductive layer, wherein the second conductive layer and the first conductive layer are superimposed, the bond pad layer and the second conductive layer have a surface area less than that of the first conductive layer, and the conductive contacts electrically connect the first conductive layer to form a noise shield from the sides and bottom of the bond pad layer.

2. The bond pad structure as claimed in claim 1, wherein the conductive contacts are electrically isolated from the second conductive layer.

3. The bond pad structure as claimed in claim 1, the conductive contacts surround the second conductive layer.

4. The bond pad structure as claimed in claim 1, wherein the conductive contacts extend along opposing sides of the first conductive layer.

5. The bond pad structure as claimed in claim 1, wherein the first conductive layer has a surface of about 3000˜6000 μm².

6. A semiconductor device, comprising:
a first dielectric layer with a first conductive layer and a signal line therein, wherein the first conductive layer is grounded;
a second dielectric layer with a second conductive layer, a plurality of conductive contacts and a conductive line therein, overlying the first dielectric layer;
a bond pad layer overlying the second conductive layer; and
a conductive bond over the bond pad, wherein the second conductive layer and the first conductive layer are superimposed, the bond pad layer and the second conductive layer have a surface less than that of the first conductive layer, and the conductive contacts electrically connect the first conductive layer to form a noise shield from the sides and bottom of the bond pad layer such that a coupling noise induced by operation of the conductive bond is reduced.

7. The semiconductor device as claimed in claim 6, wherein the conductive contacts are electrically isolated from the second conductive layer.

8. The semiconductor device as claimed in claim 6, the conductive contacts surround the second conductive layer.

9. The semiconductor device as claimed in claim 6, wherein the conductive contacts extend along opposing sides of the first conductive layer and are parallel to a direction in which the signal line extends.

10. The semiconductor device as claimed in claim 6, wherein the first conductive layer has a surface of about 3000˜7000 μm².

11. The semiconductor device as claimed in claim 6, further comprising a substrate with a device therein underlying the first dielectric layer.

12. The semiconductor device as claimed in claim 11, wherein the device is located at a place substantially under the bond pad layer.

13. The semiconductor device as claimed in claim 11, wherein the conductive bond is operated under a clock frequency of above 1 GHz.

14. The semiconductor device as claimed in claim 6, wherein the signal line is about 0.1˜5 μm from the bonding pad structure.

15. A method for reducing coupling noise, comprising:
providing a dielectric layer with a signal line therein and a bond pad structure thereon, wherein the bond pad structure comprises a bond pad layer formed on the dielectric layer and a conductive bond over the bond pad layer; and
providing a shielding structure embedded in the dielectric layer at a place under the bond pad layer, wherein the shielding structure comprises a grounded conductive layer and a plurality of contacts formed over the grounded conductive layer, extending along opposing edges of the bond pad layer.

16. The method as claimed in claim 15, wherein the signal line extends along a direction parallel to opposing edges of the bond pad layer.

17. The method as claimed in claim 15, wherein the conductive contacts are electrically isolated from the grounded conductive layer.

18. The method as claimed in claim 15, the conductive contacts surround the grounded conductive layer.

19. The method as claimed in claim 15, wherein the grounded conductive layer has a surface of about 3000˜7000 μm².

20. The method as claimed in claim 15, wherein the signal line is about 0.1˜5 μm from the bond pad structure.
